(19) United States
(12) Patent Application Publication
(10) Pub. No.: US 2014/0225635 A1
(43) Pub. Date: Aug. 14, 2014

(54) ALL-DIGITAL PHASE LOCKED LOOP SELF TEST SYSTEM

(71) Applicant: QUALCOMM INCORPORATED, San Diego, CA (US)

(72) Inventor: Sachin D. Dasnurkar, San Diego, CA (US)

(73) Assignee: QUALCOMM INCORPORATED, San Diego, CA (US)

(21) Appl. No.: 13/764,375

(22) Filed: Feb. 11, 2013

(51) Int. Cl. G01R 31/3187

(52) U.S. Cl. CPC G01R 31/3187
USPC 324/750.3

(57) ABSTRACT

A method and apparatus for an all-digital built in self test (BIST) of a phase locked loop includes a phase detector (PD), wherein the PD produces a digital signal describing a comparison between a reference signal and a feedback signal, and an all-digital programmable BIST coupled to the PD and a charge pump (CP). The BIST includes a digital counter to accumulate the digital signal, and a communication link, which provides the accumulated digital signal from the counter to automatic test equipment (ATE), which determines whether the PLL is operating correctly based on the accumulated digital signal. The method includes injecting signal pulses into the PLL to adjust a signal of the PLL, accumulating in a digital counter a digital signal that describes a comparison between the PLL feedback and reference signals, and determining whether the PLL is operating correctly based on the accumulated digital signal in the digital counter.

### TECHNICAL FIELD

The present disclosure relates generally to electronic devices for communication systems. More specifically, the present disclosure relates to an all digital phase locked loop (PLL) self test system.

### BACKGROUND

Electronic devices (cellular telephones, wireless modems, computers, digital music players, Global Positioning System units, Personal Digital Assistants, gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of digital circuits to support the processor and other parts of the device.

This increased complexity has led to an increased need for testing that can test digital circuits and/or digital systems. Testing may be used to verify or test various parts of devices, such as pieces of hardware, software or a combination of both.

Many different kinds of electronic devices may benefit from testing. Different kinds of such devices include, but are not limited to, cellular telephones, wireless modems, computers, digital music players, Global Positioning System units, Personal Digital Assistants, gaming devices, etc. One group of devices includes those that may be used with wireless communication systems. As used herein, the term “mobile station” refers to an electronic device that may be used for voice and/or data communication over a wireless communication network. Examples of mobile stations include cellular phones, handheld wireless devices, wireless modems, laptop computers, personal computers, etc. A mobile station may alternatively be referred to as an access terminal, a mobile terminal, a subscriber station, a remote station, a user terminal, a terminal, a subscriber unit, user equipment, etc.

For the system to perform its intended mission with high availability, testing and diagnosis must be quick and effective. In mixed digital and analog systems, testing may be considerably more complex. In many cases the equipment used to test a device is a separate piece of automatic test equipment (ATE) from the device under test (DUT). Some testing that takes place is performed substantially by the ATE. Mixed signal systems impose a complex set of demands on ATE, which may need to be capable of high frequency analog as well as standard digital interfaces. In the case of mixed signal systems, and especially those including high frequency phase locked loop circuits, direct testing of circuit nodes may perturb circuit operation due to added probe capacitance. Systems involving high frequency performance, and especially where Phase Locked Loop (PLL) oscillators of various frequencies may be used, may need to test systems operating over a wide frequency range. Testing may therefore require expensive high performance ATE capable of both digital and high frequency (RF) operation. Such testing may be slow, incurring added expense. Benefits may therefore be realized by providing improved methods and apparatus for providing built in self tests for electronic devices and/or components used in electronic devices.

An increasingly attractive alternative is built-in self-test (BIST)—that is, self test implemented in the hardware itself. One problem with conventional PLL BIST may be that certain nodes are analog in nature. Therefore, any excessive loading caused by additional BIST circuitry may change the PLL characteristics. The feedback loop, which typically includes a divide-by-N (DBN) module, may be digital in nature but phase sensitive since its output is fed to a phase detector and directly affects the phase of the PLL output. Any additional delay in the feedback path causes a delayed phase of the feedback signal and the PLL output phase, which may cause a mismatch with the input signal phase. This added phase noise may be a concern in certain precision clocking applications and hence not universally acceptable in a BIST solution. Therefore, a BIST scheme that operated purely in digital mode, avoiding analog processes, may offer significant advantage to the integrity of the PLL in both mission and test mode, and may reduce the on-chip real estate needs.

Furthermore, a well designed BIST will be independent of the frequency of operation of the DUT and preferably operate in an entirely digital mode, avoiding direct testing of analog circuit nodes with reactively perturbing node measurements. An all-digital frequency independent BIST may be implemented in PLL circuits that is virtually universally applicable without redesign. Programmability of each BIST from the ATE may be sufficient to satisfy a very wide range of PLL testing. All digital operation reduces the speed requirements of ATE and enables use of very low cost ATE (VLC-ATE).

There is a need in the art, therefore, for a BIST for testing PLL circuitry that may satisfy the following goals: (1) complete self testing of all blocks, i.e., the entire feedback system loop is to be maintained during the test; (2) avoid disturbing any sensitive analog or digital nodes with added circuitry; (3) generate most required internal stimuli by the DUT to ensure that individual blocks do not need to be tested externally; (4) be compatible with low functionality VLC-ATE to contain production test cost while optimizing area overheads; (5) be independent of the PLL operating frequency; and (6) enable parametric, catastrophic failure and alternate testing methods.

### SUMMARY

In an embodiment, an apparatus for performing an all digital built in self test (BIST) of a phase locked loop (PLL) is provided. The apparatus includes a phase detector (PD), wherein the PD produces a digital signal describing a comparison between a reference signal and a feedback signal, an all-digital programmable all-digital BIST coupled to the PD and the CP, wherein the BIST controller includes a digital counter to accumulate the digital signal, and a communication link. The communication link provides the accumulated digital signal from the counter to automatic test equipment (ATE) to determine whether the PLL is operating correctly based on the accumulated digital signal.

In a further embodiment, a method of self testing a phase locked loop (PLL) built in self test (BIST) is provided. The method includes injecting a series of signal pulses into the PLL to adjust a signal of the PLL, accumulating in a digital counter a digital signal descriptive of a comparison between the PLL signal and a reference signal, and determining whether the PLL is operating correctly based on the accumulated digital signal in the digital counter.

A further embodiment provides an apparatus for performing an all digital built in self test (BIST) of a phase locked loop (PLL) includes a means for phase detection (PD), wherein the PD means produces a digital signal that describes a comparison between a reference signal and a feedback signal, an all-digital programmable BIST control means coupled to the PD, wherein the controller means includes a digital counting means to accumulate the digital signal, and a communication means, wherein the communication means provides the accumulated digital signal from the counting means for an automatic test equipment (ATE) to determine whether the PLL is operating correctly based on the accumulated digital signal.

A still further embodiment provides a computer readable media including program instructions which when executed by a processor cause the processor to perform the method of self testing a phase locked loop (PLL) built in self test (BIST) includes injecting a series of signal pulses into the PLL to adjust a signal of the PLL, accumulating in a digital counter a digital signal descriptive of a comparison between the PLL signal and a reference signal and determining whether the PLL is operating correctly based on the accumulated digital signal in the digital counter.

### BRIEF DESCRIPTION OF THE DRAWINGS

FIG. 1 illustrates one configuration of a wireless communication system, in accordance with certain embodiments of the disclosure.

FIG. 2 illustrates a block diagram of an example of electronic components capable of transmitting in accordance with certain embodiments of the disclosure.

FIG. 3 shows a system for production testing of a device under test (DUT), according to an embodiment of the disclosure.

FIG. 4 is a block diagram illustrating a phase locked loop (PLL) that may be used with the present systems and method, according to an embodiment of the disclosure.

FIG. 5 is a block diagram illustrating a system for a PLL built in self test (BIST), according to an embodiment of the disclosure.

FIG. 6 is a block diagram illustrating a BIST controller, according to an embodiment of the disclosure.

FIG. 7 is a state diagram for a PLL BIST test mode, according to an embodiment of the disclosure.

FIG. 8 is a flow diagram illustrating a method for a phase locked loop BIST of the disclosure.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Furthermore, various aspects are described herein in connection with a terminal, which can be a wired terminal or a wireless terminal. A terminal can also be called a system, device, subscriber unit, subscriber station, mobile station, mobile, mobile device, remote station, remote terminal, access terminal, user terminal, communication device, user agent, user device, or user equipment (UE). A wireless terminal may be a cellular telephone, a satellite phone, a cordless telephone, a Session Initiation Protocol (SIP) phone, a wireless local loop (WLL) station, a personal digital assistant (PDA), a handheld device having wireless connection capability, a computing device, or other processing devices connected to a wireless modem. Moreover, various aspects are described herein in connection with a base station. A base station may be utilized for communicating with wireless terminal(s) and may also be referred to as an access point, a Node B, or some other terminology.

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The techniques described herein may be used for various wireless communication networks such as Code Division Multiple Access (CDMA) networks, Time Division Multiple Access (TDMA) networks, Frequency Division Multiple Access (FDMA) networks, Orthogonal FDMA (OFDMA) networks, Single-Carrier FDMA (SC-FDMA) networks, etc. The terms “networks” and “systems” are often used interchangeably. A CDMA network may implement a radio technology such as Universal Terrestrial Radio Access (UTRA), CDMA2000, etc. UTRA includes Wideband CDMA (W-CDMA). CDMA2000 covers IS-2000, IS-95 and technology such as Global System for Mobile Communication (GSM).

An OFDMA network may implement a radio technology such as Evolved UTRA (E-UTRA), the Institute of Electrical and Electronics Engineers (IEEE) 802.11, IEEE 802.16, IEEE 802.20, Flash-OFDAM®, etc. UTRA, E-UTRA, and GSM are part of Universal Mobile Telecommunication System (UMTS). Long Term Evolution (LTE) is a release of UMTS that uses E-UTRA. UTRA, E-UTRA, GSM, UMTS, and LTE are described in documents from an organization named “3^{rd} Generation Partnership Project” (3GPP). CDMA2000 is described in documents from an organization named “3^{rd} Generation Partnership Project 2” (3GPP2). These various radio technologies and standards are known in the art. For clarity, certain aspects of the techniques are described below for LTE, and LTE terminology is used in much of the description below. It should be noted that the LTE terminology is used by way of illustration and the scope of the disclosure is not limited to LTE. Rather, the techniques described herein may be utilized in various application involving wireless transmissions, such as personal area networks (PANs), body area networks (BANs), location, Bluetooth, GPS, UWB, RFID, and the like. Further, the techniques may also be utilized in wired systems, such as cable modems, fiber-based systems, and the like.

Single carrier frequency division multiple access (SC-FDMA), which utilizes single carrier modulation and frequency domain equalization has similar performance and essentially the same overall complexity as those of an OFDMA system. SC-FDMA signal may have lower peak-to-average power ration (PAPR) because of its inherent single carrier structure. SC-FDMA may be used in the uplink communications where the lower PAPR greatly benefits the mobile terminal in terms of transmit power efficiency.

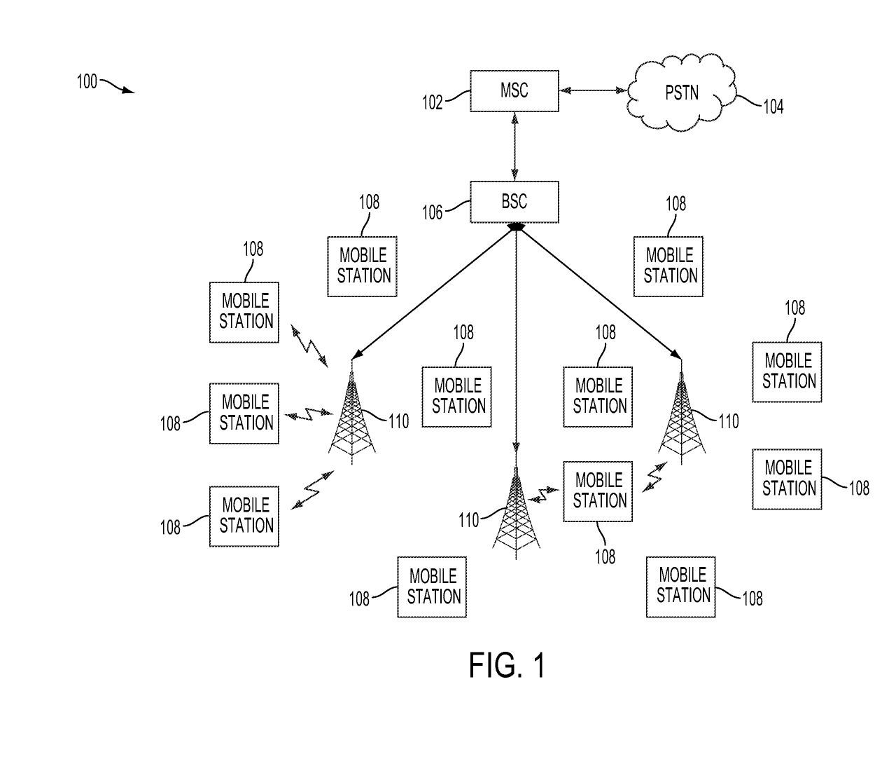

FIG. 1 illustrates a wireless system 100 that may include a plurality of mobile stations 108, a plurality of base stations 110, a base station controller (BSC) 106, and a mobile switching center (MSC) 102. The system 100 may be GSM, EDGE, WCDMA, CDMA, etc. The MSC 102 may be configured to interface with a public switched telephone network (PTSN) 104. The MSC may also be configured to interface with the BSC 306. There may be more than one BSC 106 in the system 300. Each base station 110 may include at least one sector, where each sector may have an omnidirectional antenna or an antenna pointed in a particular direction radially away from the base stations 110. Alternatively, each sector may include two antennas for diversity reception. Each base station 110 may be designed to support a plurality of frequency assignments. The intersection of a sector and a frequency assignment may be referred to as a channel. The mobile stations 108 may include cellular or portable communication system (PCS) telephones.

During operation of the cellular telephone system 100, the base stations 110 may receive sets of reverse link signals from sets of mobile stations 108. The mobile stations 108 may be involved in telephone calls or other communications. Each reverse link signal received by a given base station 110 may be processed within that base station 110. The resulting data may be forwarded to the BSC 106. The BSC 106 may provide call resource allocation and mobility management functionality including the orchestration of soft handoffs between base stations 110. The BSC 106 may also route the received data to the MSC 102, which provides additional routing services for interfacing with the PSTN 104. Similarly, the PTSN 104 may interface with the MSC 102, and the MSC 102 may interface with the BSC 106, which in turn may control the base stations 110 to transmit sets of forward link signals to sets of mobile stations 108.

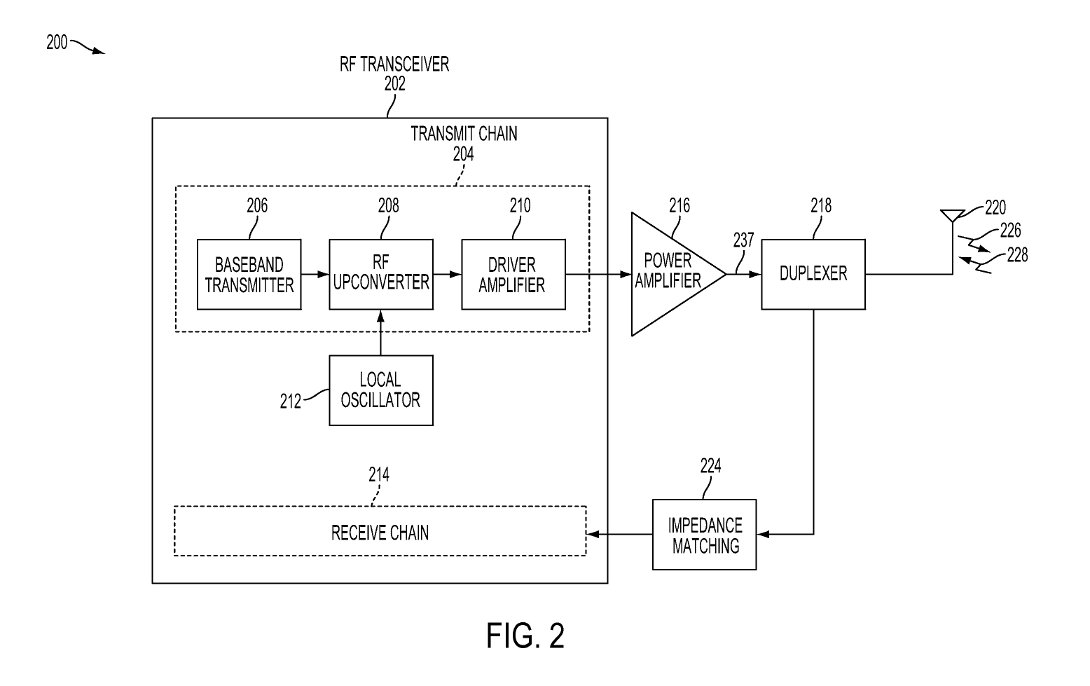

FIG. 2 is a block diagram illustrating one example of electronic components, 200, capable of transmitting. The electronic components 200 may be part of a mobile station 108, a base station 110, or any other type of device that may transmit. The electronic components 200 may include a power amplifier (PA) 216. In one scenario the tests may be conducted before the components 200 are marketed, that is, before an end user acquires the components 200. Individual components illustrated in FIG. 2 may also be tested prior to assembly into the portable electronic device. The device may be further tested once assembled. In one example, the configuration 200 may include a radio frequency (RF) transceiver 202. The transceiver 202 may transmit outgoing signals 226 and receive incoming signals 228 via an antenna 220. A transmit chain 204 may be used to process signals that are to be transmitted and a receive chain 214 may be implemented to process signals received by the transceiver 202. An incoming signal 228 may be processed by a duplexer 218 and impedance matching 224 of the incoming signal 228 may occur. The incoming signal 228 may then be processed by the receive chain 214.

Transmit chain 204 prepares signals for transmission by the antenna 220. Transmit chain 204 includes baseband transmitter 206, RF upconverter 208, and driver amplifier 210. The baseband transmitter 206 may also include a filter (not shown) to filter out noise that may be associated with the signal. The signal to be transmitted is prepared by the baseband transmitter 206 and may be upconverted to a high frequency signal by an RF upconverter 208. The upconverter 408 may be under the control of a local oscillator 212. A driver amplifier 210 may amplify the signal and the signal may pass through the PA 216.

In one configuration, the signal to be transmitted may be fed through the transmit chain 204 as described above, into the PA 216, and PA output 237 may be passed through a duplexer 218. The duplexed signal 239 may be measured (rather than measuring the output signal 226 from the antenna 220) as part of a testing process for the completed wireless communication device. During the testing of PA 216, measuring equipment 230 may be connected to the output of the duplexer 218 (i.e., the duplexed signal 239). The equipment 230 may include amplitude measuring equipment or functionality 232 and phase measuring equipment or functionality 234. The measuring equipment 230 may be implemented by a computing device that includes a processor, memory, a display, communication interfaces, and the like.

An integrated circuit for a phase locked loop (PLL) built in self test (BIST) is disclosed. The integrated circuit includes a phase detector that produces a digital signal that describes a comparison between a reference signal and a feedback signal. In an alternate embodiment, the integrated circuit may include an N-divider (DBN) that provides the feedback signal to the phase detector. A voltage controlled oscillator (VCO) may be coupled to the N-divider.

A method for a PLL BIST is also disclosed. A digital signal is produced that describes a comparison between a reference signal and a feedback signal. The digital signal is routed to the phase detector (PD) in the PLL. The digital signal is accumulated for the test mode duration and means are provided for the ATE to read the analog value of this accumulation. Whether the PLL is operating correctly is determined based on the accumulated signal by the ATE.

An apparatus for performing a PLL BIST is also disclosed. The apparatus includes a phase detector that is configured to produce a digital signal that describes a comparison between a reference signal and a feedback signal. The apparatus also includes a BIST controller that accumulates the PD output signal during test mode instead of routing it to the charge pump, as it is routed during functional mode. The apparatus also includes a low frequency analog communication pin that provides the accumulated signal for ATE to determine whether the PLL is operating correctly based on the accumulated signal.

A wireless communication network may provide communication for a number of mobile stations, each of which may be serviced by a base station. A base station may alternatively be referred to as an access point, a Node B, or some other terminology. Base stations and mobile stations may make use of integrated circuits with mixed signal circuitry. However, many different kinds of electronic devices, in addition to the wireless devices mentioned, may make use of integrated circuits with mixed signal circuitry. Production of integrated circuits may result in process variations that affect the operation of the mixed signal circuitry. Accordingly, a broad array of electronic devices may benefit from the systems and methods disclosed herein.

PLLs are extensively used in modern System on a Chip (SoC) and as communication modules for clock regeneration and timing synchronization. The typically low jitter characteristics make them attractive in frequency synthesis applications, while the ease of generating frequency harmonics makes them stable clock generators. When treated as a black box with the internal complexity masked, the PLL module receives an input waveform and generates an output waveform which is an integral multiple in frequency of the input. PLLs may be mixed signal modules that may include multiple sensitive blocks internally and may need parametric testing to ensure complete specification compliance. Since a PLL may be commonly used as a clock generator, the quality of the output waveform may be especially important for the dependent blocks. This requires jitter measurement/settling time/output swing testing of the PLL, which may constitute qualitative tests, along with a simple PLL-lock testing that targets gross failures.

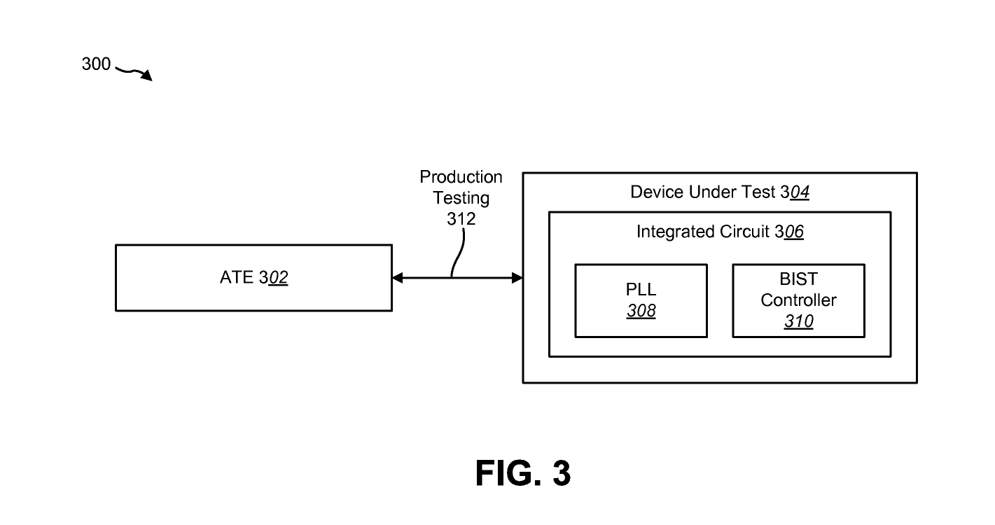

FIG. 3 is a block diagram of a system 300 for production testing 312 of a device under test (DUT) 304 with mixed signal circuitry. In one configuration, the DUT 304 may be a wireless device such as a mobile station or a base station. Alternatively, the DUT 304 may be a chip for use in a wireless device. In other configurations, the DUT 304 may not be a wireless device or part of a wireless device. The DUT 304 may include an integrated circuit 306. The integrated circuit 306 may include mixed signal circuitry. Mixed signal circuitry may be circuitry that includes both analog and digital circuitry. In one configuration, the integrated circuit 306 may include a PLL 308.

PLLs are present on a wide range of SoCs. In some cases, the PLL 308 may be the only mixed signal component present on the DUT 304. This may complicate the testing strategies because the remaining pure digital DUT 304 modules may be tested with the help of simple SCAN/at-speed functional tests that are digital in nature and have minimal ATE 302 hardware requirements. Such situations may be dealt with by performing a simple go-no-go frequency lock test where the PLL 308 output signal is latched by ATE 302 receive resources and the output is tested for a frequency lock achieved within a specified time duration. These tests, however, tend to be basic in nature and may not check for PLL 308 output phase, jitter, or other performance specifications, depending on ATE 302 resources available. Most such tests do not perform specification checks for PLL 308 output jitter (period or amplitude) or any process variations that may be compensated in the feedback loop and may cause reliability concerns in field use.

The two factors mentioned above, common use and limited structural testability, emphasize the need to provide built-in testability to enable quality production testing. The mixed signal nature of many PLL 308 sub-blocks, however, may make such BIST arrangements complicated.

A digital ATE 302 may enable full production-quality testing 312 of integrated circuits 306 that include PLLs 308 by using a BIST. One way of utilizing low cost ATE 302 such as digital ATE 302 to test mixed signal integrated circuits 306 is with an on-chip BIST Controller 310. The BIST controller 310 may generate an input or signal for testing purposes.

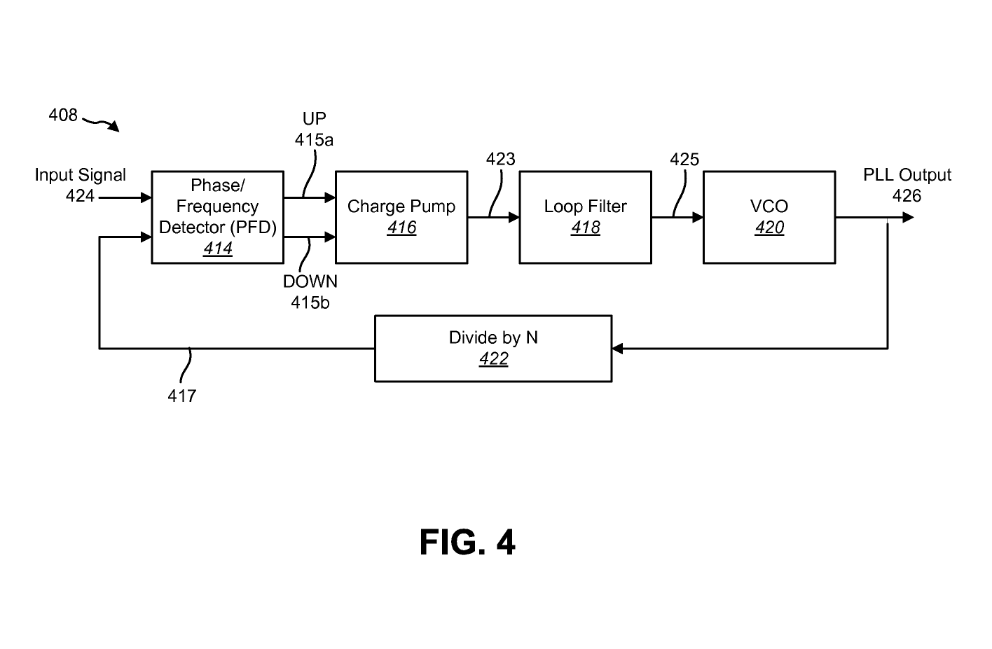

FIG. 4 is a block diagram illustrating a PLL 408 that may be used with the present systems and methods. The PLL 408 may include a phase and frequency detector, a charge pump (CP) 416, a loop filter (LF) 418, a voltage controlled oscillator (VCO) 420, and a divide-by-N (DBN) module 422. While a phase and frequency detector is described in the following configurations, a phase detector (PD) 414 without a frequency detector may also be used. Furthermore, the PLL 408 may receive an input reference signal 424 and output an output signal 426.

In one embodiment, the PD 414 may compare the reference signal 424 to the output of the divide by N module (DBN) 422 in the feedback loop. The output 417 of the DBN 422 may be a signal with a frequency equal to the frequency of the output signal, PLL Output 426, divided by an integer parameter N. The parameter N may be chosen to produce a desired tuning voltage for the VCO 420. The PD 414 may determine any differences in phase and/or frequency between the output 417 of the DBN 422 and the reference signal 424 and express this difference as “pump up” 415a or “pump down” 415b pulses to the charge pump 416. The charge pump 416 may then provide charge to the loop filter 418 that may filter the charge pump 416 output 423 to provide a voltage 425 to the tuning port of the VCO 420. For example, the PD 414 may generate a digital output signal 415a/b including high/low pulses of varying lengths. The charge pump 416 may receive this signal 415 and produce an output 423 corresponding to the pump up 415a and/or pump down 415b signals from the PD 414. The charge pump 416 output 423 may subsequently be filtered by the loop filter 418 to provide a stable voltage level input 425 to the VCO 420.

The PD 414 output 415 may be a digital switching signal while the charge pump 416 and loop filter 418 may have analog outputs. Upon receiving a voltage level input signal 425 from the charge pump 416 via the loop filter 418, the VCO 420 may generate an output 426 oscillation signal that is a function of the input voltage 425 provided by the loop filter 418. The VCO 420 output, (i.e., the PLL output 426), may be fed to the PD 414 after division by the DBN 422, where the PD 414 may then compare it with the input signal 424 and generate a phase-differential dependent digital output switching signal. In other words, the PD 414 may output a signal including the UP 415a and DOWN (DN) 415b signals descriptive of the comparison between the input signal 424 and the feedback signal 417.

One problem with conventional PLL BIST may be that the charge pump 416 and loop filter 418 output nodes are analog in nature. Therefore, any excessive loading caused by analog coupling to the BIST circuitry may change the PLL 408 characteristics. The feedback loop, which typically includes the DBN 422, may be digital in nature but phase sensitive since its output 417 is fed to the PD 414 and directly affects the phase of the PLL output 426. Any additional delay in the feedback path causes a delayed phase of the feedback signal 417 and the PLL output 426 phase, which may cause a mismatch with the input signal 424 phase. This added phase noise may be a concern in certain precision clocking applications and hence not universally acceptable in a BIST solution.

Multiple approaches to designing a BIST mechanism for PLLs 408 have been attempted, where each may have its advantages and drawbacks. It would be desirable to provide a BIST mechanism that minimally affects internal loading conditions of the PLL 408 and uses minimal ATE 302 resources to ensure compatibility with very low cost (VLC)-ATE 302. One possible BIST scheme is an all digital BIST scheme for testing catastrophic faults in PLLs 408. Although the ATE 302 resources required may be limited in such a scheme, this provides a non-parametric gross failure screening test method. Another possible scheme is to digitally program the charge pump 416 input and observe the loop filter 418 output 425. However, this sampling at the VCO 420 input node may add excessive capacitance at that node and may affect the PLL 408 settling time characteristics. This approach also may not allow a complete self test of the DUT 304 since some internal modules are left out of the BIST path.

Another possible BIST approach may involve adding duplicate modules or using ATE 302 to provide some of the internal node voltages. This approach also may not completely enable self test since the stimuli are provided externally, i.e., if the loop filter 418 output/VCO 420 input is provided externally using a Parametric Pin Measurement Unit (PPMU) in the ATE 302, the CP 416 and LF 418 blocks may remain untested and an additional mechanism would be required to test these blocks. Since the PLL 408 is a closed loop system, self testing of the internal modules is optimum as it reduces external resource requirements and is likely to have the minimal test time overhead.

Another possible BIST scheme may use a test controller module that can be used to control the CP 416 input in test mode. However, the PD 414 within the PLL 408 does not drive the CP 416 and hence it is not tested in the loop. Other possible BIST schemes may include a BIST mechanism with a test mode that can select between PLL 408 output fed to the PD 414 as against added line delay. Still another possibility is to perform parametric testing apart from simple catastrophic failure testing proposed in many other schemes. This may require additional circuits in the feedback loop and may result in some (even if minor) phase shift as well as frequency dependence on the input signal as the at-speed signal in the feedback loop is captured and used.

In addition to minimizing phase noise and external loading, the present systems and methods disclosed may ensure compatibility with a new generation of VLC-ATE 302 developed by reducing ATE 302 functionality. VLC-ATE 302 may cost a fraction of the fully functional equipment and are increasingly used for providing low-cost solutions for production test. Maintaining test quality, in light of these limited resources available, is also addressed by the present systems and methods.

The cost of testing for a large number of specifications can be very high. Alternate testing is an approach for analog integrated circuit (IC) testing that involves formulation of a test plan to combine statistical correlation with conventional testing methods. In alternate testing, the performance characteristics of the DUT 304 may be predicted from the outputs under a particular set of stimuli. The input stimulus may be a subset of the entire possible set of inputs and may be used only to measure certain system parameters from which the other parameters may be predicted by calculation or extrapolation. Reduction in test time and complexity is the primary goal of alternate testing and it may offer a significant cost reduction over conventional analog testing for each specification separately.

Parameter mapping can be defined as the process of mapping variation of one parameter to another correlated parameter in order find a mathematical or statistical relation between the two. Alternate testing and parameter mapping may both be applied to a complex mixed signal feedback-enabled system like a PLL 408 where multiple internal and external components affect and are dependent on the functioning of the DUT 304. The relationship between various parameters such as the PLL output 426 frequency, Fₒᵤₜ, and the VCO 420 input node voltage, V_{ctrl}, may be described in equation (1) as follows:

Fₒᵤₜ=a₀+a₁V_{ctrl}+a₂V²_{ctrl}+a₃V³_{ctrl}+ . . . (1)

where a₀, a₁, etc., have deterministic values. Some other parametric relationships such as the one between transistor current drive and PLL 408 locking time may be statistical in nature.

Parametric relations, which are discrete in nature, may not fit a deterministic functional relation but may be represented as matrices (shown in equation (2)) where the matrix A_{i×k} represents the transfer relation between an input set I_{k×j} and a response set F_{i×j},

F_{i×j}=A_{i×k}XI_{k×j} (2)

Alternate testing principles may be applied to any mixed signal circuit with multiple internal nodes, where the nodes and output are inter-dependent. PLL is a closed loop system and its behavioral model can be defined in terms of the transfer functions between the building blocks. Parametric relations between various internal nodes and the functional output for a PLL can be explained as follows: when an input frequency signal at frequency fₒₚᵣ is applied to a PLL 408 with a loop multiplier of n, the PLL 408 attempts to latch to a frequency equal to n×fₒₚᵣ with the same phase as the input signal within the time interval t_{latching}. The phase detector PD 414 signal is instantaneously proportional to the phase and frequency difference between fₒₚᵣ and the PLL output 426 signal at the measurement instant t′. This dependence may be represented as shown in equation (3) as follows:

P[fₒₚᵣ;f_{PLL};t′] [symbol] P[PDₒᵤₜ;t′] (3)

where P[p1]→is the parametric space matrix for a parameter p1.

The parametric set P[PDₒᵤₜ; t′] is finitely bound and can be well characterized using SPICE (Simulation Program with Integrated Circuit Emphasis, a general-purpose, open source analog electronic circuit simulator that is used in integrated circuit and board-level design to check the integrity of circuit designs and to predict circuit behavior).

simulations for all the independent variables in Equation (3). The set of PDₒᵤₜ is a bijective function of [fₒₚᵣ; f_{PLL}; t′] with a finite deterministic statistical confidence for a stable and functional PLL during lock-mode. The value of [PDₒᵤₜ] may be predicted with certain statistical confidence at an instant t′ if the variables operational frequency fₒₚᵣ and PLL frequency f_{PLL} can be measured.

Similar relationships may exist between the remaining internal system nodes. The CPₒᵤₜ signal may be a function of the PD output 426 and when considered over an interval [0,t′], it may be a bijective relation represented by the following equation (4):

P[PDₒᵤₜ,0,t′] [symbol] P[CPₒᵤₜ] (4)

The LF 418 and VCO 420 may have a similar bijective relationship:

P[CPₒᵤₜ,0,t′] [symbol] P[LFₒᵤₜ,0,t′] (5)

The bijective relationship between the CP 416 and the LF 418 may be established over a specified time interval [0,t′] since the node voltages are analog in nature and are a function of the measurement window during PLL 408 locking process.

P[LFₒᵤₜ] [symbol] P[VCOₒᵤₜ] (6)

The bijective relationship between the LF 418 and the VCO 420, shown in equation (6), may be established instantaneously (while including propagation delays) and may represent the relationship between the voltage node and the effective frequency output.

The present systems and methods may use the bijective relationship between PD and CP in equation (4) to perform parametric testing of the PLL 408. While accessing the common node between the PD 414 and the CP 416, the remaining PLL 408 may be treated as a closed loop with successive bijective-related sub-blocks, e.g., the LF 418, the VCO 420, and the divide by N module 422. An input vector i[CPᵢₙ], which is a subset of the vector set P[CPᵢₙ], may be applied to the CP 416 using an external driver, and the corresponding output vector from PD block i[PDₒᵤₜ] on the UP/DOWN nodes is recorded by using a digital counter included in the BIST scheme. The vector i[PDₒᵤₜ] may then be observed over a time interval [0,t′] and compared with simulation data to compare the accumulated voltage counter values for the UP/DOWN nodes. The bijective relations are valid for this analysis as the CPᵢₙ vector is injected and observe the closed loop response on PDₒᵤₜ node, isolated when using the test mode. By including the tolerance limits for the value of the accumulated vector i[PDₒᵤₜ], a pass/fail decision can be made by the ATE 302.

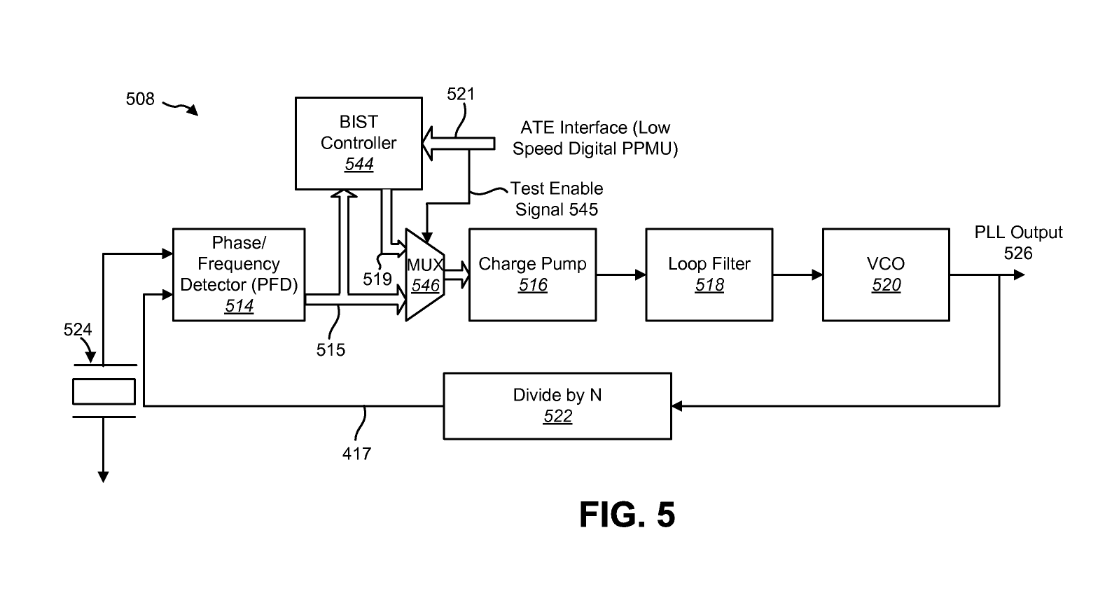

FIG. 5 is a block diagram illustrating a system for a PLL 508 BIST. In light of the problems with conventional PLL BISTs, the systems and methods described herein may have the following goals: (1) complete self testing of all blocks, i.e., the entire feedback system loop is to be maintained during the test; (2) not disturb any sensitive analog or digital nodes with added circuitry; (3) generate most required internal stimuli by the DUT 304 to ensure that no individual blocks need to also be tested externally; (4) be compatible with low functionality VLC-ATE to contain production test cost while optimizing area overheads; (5) be independent of the PLL 508 operating frequency; and (6) enable parametric, catastrophic failure and alternate testing methods. Various configurations of the present systems and methods may not necessarily achieve the above goals.

Accordingly, the PLL 508 BIST scheme in FIG. 3 may include a BIST controller 544 that may act as a programmable stimulus generator as well as an observation module. The BIST controller 544 may be positioned between the PD 514 output and the CP 516 input. The PLL 508 may include a charge pump 516, loop filter 518, VCO 520, and divide by N module 522 illustrated in FIG. 3 that operate similarly to the charge pump 216, loop filter 218, VCO 220, and divide by N module 422 described in FIG. 2. The digital output 515 of the PD 514 may be fanned out to the BIST controller 544 in parallel with the mission mode connection to the CP 516. Output 319 from the BIST controller 544 may be fed to the CP 516 through a multiplexer (MUX) 546 that is connected to the PD 514 during mission mode and to the BIST controller 544 during test mode. A test enable signal 445 may be provided by the ATE 302 to enable multiplexing. A low frequency digital interface from the ATE 302 is used to program the BIST controller 544. The digital input vector 521 for programming the CP 516, that is, the pulse count in the output vector, controls conduction duration of the CP switches. The controller also reads in the PD 514 output for a specified duration after feeding in the CP 516 vector 521 and the PD output vector is fed to a programmable counter which represents the PD output signature over the test duration.

In other words, the high/low nature of the digital input, from the PD 514 or the BIST controller 544, may control the conduction of the CP 516 switches. The BIST controller 544 may also read in the PD 514 output 515 for a specified duration after feeding in the CP 516 code 521 and this signal on the PD 514 output 515 may be fed to a low pass filter (LPF) to generate a DC voltage level internally. Then, the PLL output 326 may again be processed by the divide by N module 522 and fed back 517 into the PD 514, after which the PD 514 output 515 may again be read by the BIST controller 544, filtered by a LPF, and measured as a DC voltage value. The DC voltage value may be compared to simulated data to determine whether the PLL 508 is operating correctly. A VLC-ATE 302 PPMU may then be used to measure this DC voltage value. The input pin used to scan in the CP 516 programming code 521 may be designed to be an input/output pin that is also used for this PPMU measurement.

For example, when the PLL 508 is started from a sleep mode, the input signal 524 may already be at speed. In one configuration, the input/reference signal 524 with a predetermined frequency may be provided by a crystal oscillator and/or another suitable signal generator. At that point, the PD 514 may compare the feedback 517 to the input signal 524. Since the PLL output 326 frequency may be zero at the beginning, the PD 514 may send an UP signal 515 to the CP 516. In turn, the CP 516 may increase the voltage that is input to the VCO 520 via the loop filter 518. The VCO 520 may then output a higher PLL output 326 frequency. This loop may repeat multiple times until the PLL output 326 frequency is locked to the input signal 524. Thus, the PD 514 output 515, when accumulated in the BIST controller 544 during production testing, may create a signature of ramping up. The ATE 302 may monitor this signature to determine whether the PLL 508 is operating correctly within established parametric specifications. In other words, if the accumulated PD output 514 voltage ramps up too quickly or too slowly, this may indicate a problem with the PLL 508 operation.

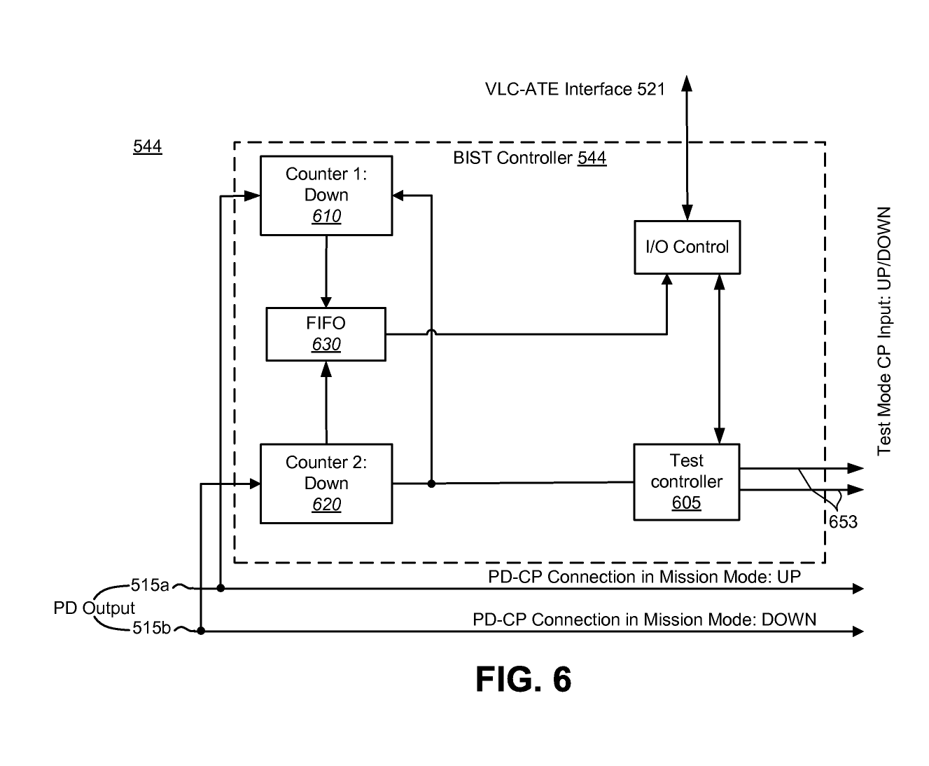

FIG. 6 is a block diagram illustrating a BIST controller 544. The input section of the BIST controller 544 may be an I/O pin of the DUT 304 which is used to scan in digital data which is routed onto the CP 516 input via the test controller 605. In test mode, the UP/DOWN outputs of the PD 514 are fed into the controller 544 and are used to drive a programmable Up counter 610 and a programmable Down counter 620. The two counters 610, 620 can be output on an ATE I/O pin 521 using a First-In-First-Out (FIFO) register 630 for further analysis and comparison. The PD output accumulation is performed over the test duration, which can be programmed by the control signals fed in from the ATE via I/O pin 521. Reliance on a programmable digital BIST controller may provide process independence where no analog measurements are required for signature observation and analysis. As disclosed, lower integrated circuit area overhead due to absence of any analog components may make this system more efficient to implement than systems requiring mixed signal analysis. The multiplexer 546 in FIG. 5 may route the BIST controller 544 to the CP 516 instead of the PD 514 during test mode.

When the test mode input is activated, data pulses are forced into the CP 516 input through the ATE IO interface 521. The test duration or count of the input pulses is controlled by the ATE and can be programmed depending on the DUT specifications and characterization results. A pulse applied on CP 516 input connects the CP 516 output node to V_{DD} or ground depending on the input used thus providing a charging or a discharging path to the CP 516 load. The conductivity of the transistors used net charge interchange that can occur during test mode.

If n pulses of duration τ are applied to the CP 516 during test mode during DUT initialization, the loop filter 518 capacitor charges to a voltage V_{LFout} which can be represented as below. The pulse duration is constant and is a characteristic of the PD module:

V_{LFout}=Q_{LF}/C_{LF}=∫₀^{τ}I_{LFdrive}/C_{LF}×n, (7)

where, I_{LFdrive} is the drive current used to drive the loop filter LF 518, Q_{LF} is the charge on the loop filter 518 capacitor, and C_{LF} is the capacitance of the loop filter 518 capacitor. In case of catastrophic failures in the CP block, the LFₒᵤₜ node would remain at ground level when the DUT is initialized. Any marginalities/process variation in the CP 516 would result in an LF output which is denoted by

V_{LFout}±δV=∫₀^{τ}[I_{LFdrive}]/[C_{LF}±δC_{LF}]. (8)

The BIST scheme, using a full-self test approach, then tests the following blocks with this parametric variation at the VCO 520 input. The VCO output frequency in test mode can be given by F_{VCO}=f[V_{LFout}], therefore, any variation in the VCO output frequency can be parametrically traced to the LF output variation. Therefore,

F_{VCO-min}=f[V_{LFout-min}] (9)

and,

F_{VCO-max}=f[V_{LFout-max}] (10)

The sequence of pulses generated by the PD 514 for this VCO 520 input signal is a function of the frequency and phase difference between the VCO output and the input frequency reference signal 524 and hence when integrated over a specified duration, represents the exact frequency difference between these two signals, thus creating a representation of the VCO output frequency:

Σ₀^{t1}V_{PDout}=f[F_{VCO}] (11)

therefore, effectively,

Σ₀^{t1}V_{PDout}=f[F_{PD,VCO,LF,LFdrive}]. (12)

The integral can be used in exchange with a series summation as the discrete pulses can be represented as their contribution to the accumulated transfer function. A catastrophic or a parametric failure in any of the sub-blocks is detectable by the above function when the cardinal relationship is violated. Detailed Monte Carlo analysis is performed in order to establish the outlier bound. Parametric or specification failures in any of the sub-blocks can be identified when the bounds for the parametric space are violated by the response, indicating the presence of a fault.

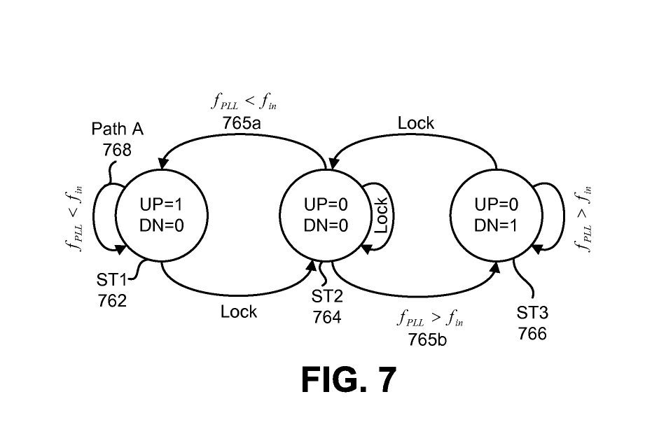

FIG. 7 is a state diagram for a PLL 508 BIST test mode. The state machine is illustrated in terms of the PDₒᵤₜ/CPᵢₙ nodes (515 and 653, respectively) and corresponding signal values. A locked PLL 508 requires no additional charging or discharging of the VCOᵢₙ node 425 and hence this state is represented by ST2 764 [symbol] [PDₒᵤₜ UP=0, and the PDₒᵤₜ DN=0). This is the stable and locked state of the PLL 508. Depending on the PD 514 design, ST2 764 may be metastable, i.e., where successive charging and discharging cycles are provided to the CP input to maintain charge neutrality. For example, the PD 514 may alternate between [UP=1;DN=0] and [UP=0;DN=1] so that the net effect on the CP 516 input node is equivalent for each UP and DN, effectively conserving the charge at CPₒᵤₜ while the PLL 508 remains in the lock state. The net PDₒᵤₜ signal in this case is [UP=½; DN=½], when averaged over two successive cycles. This may be identical in effect to the [UP=0; DN=0] condition required for lock stability.

Any charging or discharging required for the VCO 520 input node to increment or decrement the VCO 520 frequency is represented in FIG. 7 by the states STI 762 [symbol] [UP=1;DN=0] and ST3 766 [symbol] [UP=0;DN=1], respectively. In other words, if f_{PLL} becomes smaller than fᵢₙ while locked, the PLL 508 may transition 765a to state ST1 762, i.e., charge up with a [UP=1; DN=O] signal from the PD 514. However, if f_{PLL} becomes larger than fᵢₙ in while locked, the PLL 508 may transition 765b to state ST3 766, i.e., charge up with a [UP=0; DN=1] signal from the PD 514.

The BIST scheme may force the CPᵢₙ along Path A 768 when in test mode. This path may be forced externally, and the corrective signal produced by the comparison between f_{PLL} and fᵢₙ does not affect the CP 516 in test mode.

This state-machine-control may be used in test mode operation, whereas the PLL 508 may translate between the ST1 762, ST2 764, and ST3 766 during mission mode, depending on the concerning circuit conditions.

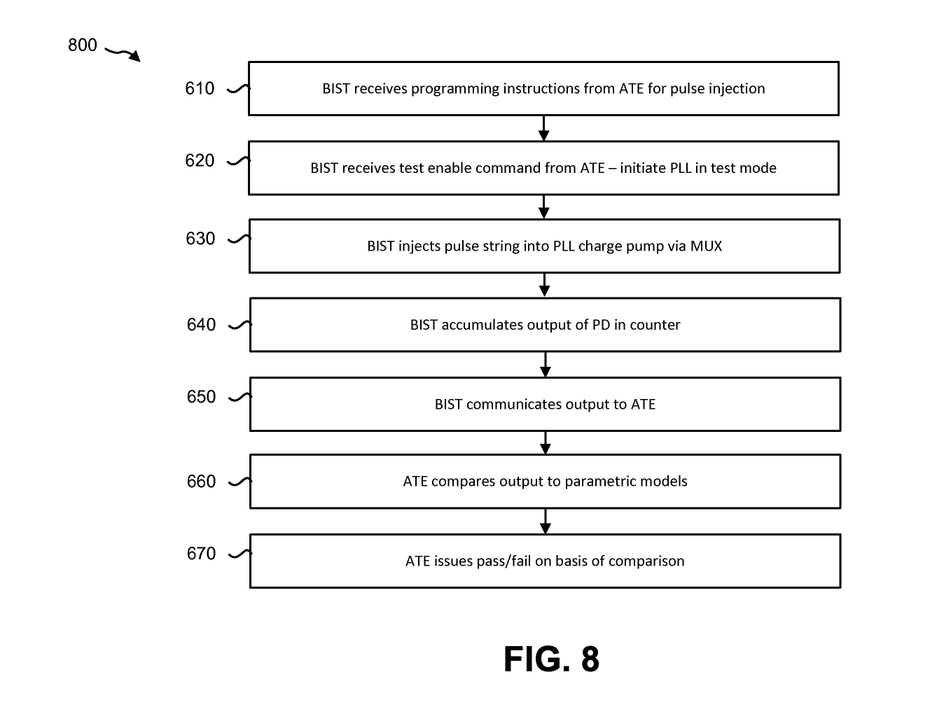

FIG. 8 is a flow diagram illustrating a method 800 for a phase locked loop 508 built in self test. When the method 800 starts (block 810), the BIST controller 544 receives programming instructions from the ATE for injection of a pulse string to the CP 516. In block 820, the MUX 546 receives a test enable command from the ATE, PLL test mode is initiated. The BIST controller then injects (block 830) the pulse string into the CP 516 via the MUX 546 as a digital signal. In this mode, the MUX receives the digital signal from the BIST controller 544, and the output of the PD 514 is a digital signal from the PD 514 descriptive of the comparison of the reference signal 524 and the feedback signal 517, wherein the output of the PD 514 is routed to the BIST controller 544, but not the MUX 546.

The PLL then proceeds to function substantially as described with respect to the PLL 408 of FIG. 6, until a signal is generated by the PD 514. The MUX 546 outputs a digital signal to the CP, which then outputs a series of analog pulses to charge the LF 518 to a voltage determined by the pulse charging. The LF 518 voltage then adjusts the VCO 520 frequency, which is divided in the DBN 522 to the feedback signal frequency, and then compared to the reference signal 524 in the PD 514. The BIST controller (in block 840) then accumulates the output of the PD 514 in the counter. Via the FIFO register 630, the BIST controller communicates (block 650) the contents of the FIFO register 630 to the ATE.

The ATE (block 860) compares the response of the PD 514 to the signal injected into the CP 516 in test mode to simulated data of a parametric model of the PLL in mission mode. On the basis of the comparison, the ATE determines (block 870) a pass/fail condition for the PLL.

In test mode, the VCO 520 may output a PLL output 326 with a frequency that corresponds to the voltage level VCO 520 input. The PLL output 326 may then be fed back, through a divide by N module 522. This signal is received by the PD 514, which may generate an output signal 515 after comparing this PLL output 326 for test-mode-stimulus with the PLL input signal 524. The integrated value of this PD 514 output signal is a function of the integrated PLL output 326 characteristics as the PLL input 524 remains unchanged. In BIST test-mode, the PD output 515 is fed to the BIST controller 544. In other words, each output of the PD 514 may be accumulated 580 in a BIST controller 544 located in between the PD 514 and the CP 516. This accumulated signal may then be analyzed against simulated data to determine 582 whether the PLL 508 is operating correctly. In other words, during normal operation start up, the PD 514 may be expected to continually output a pump up signal [UP=1; DN=0]. However, if the PD 514 output accumulates too quickly or too slowly, this may indicate a problem with the PLL 508 operation. The determining 582 may be performed in ATE 302.

Frequency independence may be an added value to any PLL 508 BIST scheme since a single silicon-on-chip/silicon-in-package (SoC/SiP) may contain either programmable PLLs 508 that run at multiple speeds or multiple PLLs 508 with different locking frequencies. Any BIST that uses at-speed signals from the feedback loop between VCO 520 and PD 514 may need to be tuned for the operational frequency of the PLL 508 and is likely to be unusable for multiple frequencies. The present stimulus and observed PD 514 output is baseband in nature, making it possible to program the scheme for multiple operating frequencies. VCO 520 output frequency is a direct function of the input reference voltage applied and by changing the pulse width of the ATE 302 stimulus applied, a different LFₒᵤₜ voltage may be programmed into the DUT 304. Design simulations may determine the CP 516 charging duration to be provided by the ATE 302 and thus the present systems and methods are completely frequency independent, i.e., usable with either multiple PLLs 508 of varying frequency or a programmable PLL 508 with a wide range of operating frequencies. Individual connections from the PDₒᵤₜ nodes in each of the blocks under test can be connected to the BIST controller 544 through a multiplexing scheme. Similarly, a multiplexer 546 that is activated in test mode for the specific block may be used to route the test stimulus to CPᵢₙ node.

If a system has a functional or mission mode operating frequency of fₒₚᵣ, it may be desirable to perform production testing at fₒₚᵣ to maintain test quality. Any mission mode testing performed at a frequency f₁ that is less than fₒₚᵣ may not assure desired at-speed performance. Conventional PLL 508 testing involves feeding the PLL 508 output to an ATE 302 resource that then records the PLL 508 output signal. PLL 508 testing done on digital testers is typically limited to performing a PLL-lock test that tests for gross defects such as the ability of a PLL 508 to lock within the maximum allowed time specification.

Thus, an ATE 302 resource used for receiving (and processing) PLL 508 output may need to operate at-speed, (e.g., at the PLL 508 output frequency) to communicate with PLL 508 output. Multiple approaches may be used in commercial ATE 302 systems. For example, some of the systems include per pin resources with high speed data reception on all pins while some of the lower cost ATE 302 systems designate certain resources that can handle high frequencies while a majority of the pin resources have a limited input frequency capability. Limiting the number of pin resources with high speed capability may complicate the DUT 304 docking board design since the specific high-speed channels/pins on the ATE 302 may need to be matched with corresponding DUT 304 resources. Further design complications and constraints may arise in case of economical multi-DUT 304 boards used in the industry.

The present systems and methods may enable testing of catastrophic, marginal as well as parametric failures in the PLL 508. Some PLL BISTs may consider fault coverage only for catastrophic failures in the internal digital and mixed signal blocks because parametric test capability may not exist for such schemes. Both types of fault coverage will be discussed, i.e., typical fault coverage and parametric fault coverage.

The BIST scheme enables testing of catastrophic and marginal failures in the PLL. The marginal failures are expected to introduce parametric failures in the PLL where design specifications may not be met due to the marginalities. The two fault domains are separately discussed in order to highlight confirmation with the typical coverage as well as additional parametric coverage.

The present PLL 508 BIST may test for parametric fault coverage. Parametric faults are likely to be caused by fabrication marginalities.

Parametric fault coverage may be represented either in terms of passing range of the observed parameters (USL>Counterₒᵤₜ>LSL) or in terms of statistical dependencies with repeated convolutions representing block interactions. Due to the closed-loop nature of the individual blocks, the observed integrated PD 514 output may be represented as a sum of convolutions of successive parameters as described in equation (13):

M[PDₒᵤₜ]=Σₘ₌ₘᵢₙ^{max} Moduleᵢ[m] Moduleᵢ₊₁[n−m] (13)

for Moduleᵢ: i^{th} module in the closed loop.

Various specification based tests may be used for parametric testing, increasing overall fault coverage for marginalities and reliability hazards. Some faults, such as an open in one of the telescopic arms of the current mirror used in the CP 516 module, may still allow the VCO 520 to be driven to a level where the PLL 508 can be locked. The remaining functional branches may carry additional or uneven current causing electromigration risk during field use of the DUT 304. This fault may be difficult to screen during a typical lock test but an intermediate value of the PDₒᵤₜ may be characterized on various process corners to identify such moderate low-slope charging devices. Similar characterization can be performed on the measured node to screen out marginal short connections.

Conventional PLL 508 testing in production is limited to testing the PLL 508 locking mechanism and passing the DUT 304 if the PLL 508 locks to the input frequency within t.sub.lock. A gross fabrication fault in the PLL 508 would disable the DUT 304 from frequency-locking while a marginal fabrication fault may cause an abnormality in the lock time. Most of the PLL 508 tests are directed at ensuring t_{lock}<tₗᵢₘᵢₜ as a rejection criterion while typically no test targets a lower limit on t_{lock}. A fabrication marginality causing voids/metal trace narrowing may increase the locking time and would be caught but a via overfill or any marginal short that causes a high current flow is likely to cause higher than nominal drive current through the charge pump, causing a frequency lock in a shorter than nominal interval. Such a marginal short is likely to escape a PLL 508 lock test, and DUT 304 level quiescent current testing may not screen this part out since the leakage current may be a fraction of the overall quiescent current. A marginal short is likely to cause reliability issues in the DUT 304 on continued operation as the excessive current drawn through the leakage path is likely to cause electro-migration, resulting in an electrical open at later stages of its operating life.

Parametric testing may provide a screen for such marginal parts since their manifestation into internal parameters is more likely to be detected than the overall system output. A closed loop system may be able to compensate for such marginalities, effectively masking the faults during testing. Driving an input signal at an internal node during test mode and observing the corresponding driver node in an ‘opened-close-loop’ system may provide the ability to perform numerical limit based testing for the internal parameter observed. Test specifications can be applied to the PDₒᵤₜ signal within the test window to screen out devices where marginal shorts are present within blocks.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An apparatus for performing an all digital built in self test (BIST) of a phase locked loop (PLL) comprising:
a phase detector (PD), wherein the PD produces a digital signal describing a comparison between a reference signal and a feedback signal;
an all-digital programmable all-digital BIST coupled to the PD and a charge pump (CP), wherein the BIST controller includes a digital counter to accumulate the digital signal; and
a communication link, wherein the communication link provides the accumulated digital signal from the counter to automatic test equipment (ATE) to determine whether the PLL is operating correctly based on the accumulated digital signal.

2. The apparatus of claim 1, wherein the counter communicates to the ATE via the communication link without affecting the operating characteristics of the phase locked loop (PLL).

3. The apparatus of claim 1, wherein the ATE programs the BIST to inject a one or more signal pulses into the CP.

4. The apparatus of claim 3, the PLL further comprising a low pass loop filter (LF) cooperatively coupled to the CP, wherein the LF accumulates charge from the CP to provide a voltage output on the basis of the one or more signal pulses injected into the CP.

5. The apparatus of claim 4, further comprising a voltage controlled oscillator (VCO) coupled to the LF, the VCO outputting a frequency on the basis of the voltage output from the LF.

6. The apparatus of claim 5, further comprising a frequency divide by N (DBN) module coupled to the VCO to output a feedback frequency signal.

7. The apparatus of claim 6, wherein the PD is coupled to the frequency DBN module, and wherein the PD receives the N divided feedback frequency signal and a reference frequency signal for the comparison.

8. The apparatus of claim 3, further comprising:
a multiplexer having an output to the CP and inputs from the PD and the BIST controller; and
a test enable switch coupled to the multiplexer to receive a control signal from the ATE, wherein the control signal determines whether the multiplexer connects the CP to the PD during a mission mode or to BIST controller in a test mode during a test mode.

9. The apparatus of claim 1, wherein the phase detector includes a frequency detector.

10. A method of self testing a phase locked loop (PLL) with a built in self test (BIST) coupled to an automatic test equipment (ATE), comprising:
injecting a series of signal pulses from the BIST based on commands from the ATE into the PLL to adjust a signal of the PLL;
accumulating in a BIST digital counter a digital signal descriptive of a comparison between the PLL signal and a reference signal; and
communicating the digital signal to the ATE to determine whether the PLL is operating correctly.

11. The method of claim 10, wherein the accumulating does not affect the operating characteristics of the phase locked loop (PLL).

12. The method of claim 10, wherein the determining whether the phase locked loop (PLL) is operating correctly comprises comparing the accumulated counter digital signal to simulated data.

13. The method of claim 12, further comprising selecting a pass or fail condition on the basis of the comparison to the simulation.

14. The method of claim 10, wherein the comparing is performed in the ATE coupled to the PLL BIST.

15. The method of claim 12, wherein the simulated data is a simulated signature of an output of a phase detector during phase locked loop (PLL) start up.

16. The method of claim 10, wherein the injecting comprises transmitting the signal pulses to a charge pump (CP) of the PLL.

17. The method of claim 16, wherein the transmitting comprises providing the signal pulses from a digital controller included in the BIST, wherein the BIST controller is programmable from the ATE.

18. The method of claim 16, further comprising outputting from the CP a charge to a low pass loop filter (LP), wherein the LF generates a voltage on the basis of the charge from the CP.

19. The method of claim 18, further comprising adjusting a voltage controlled oscillator (VCO) output frequency signal on the basis of the voltage supplied from the LP.

20. The method of claim 19, further comprising producing in a phase detector (PD) the digital signal descriptive of the comparison between the reference signal and a signal representative of the VCO output frequency signal.

21. The method of claim 20, further comprising dividing the VCO output frequency signal by an integer N to provide the signal representative of the VCO output frequency signal.

22. An apparatus for performing an all digital built in self test (BIST) of a phase locked loop (PLL) comprising:
means for phase detection (PD), wherein the PD means produces a digital signal that describes a comparison between a reference signal and a feedback signal;
all-digital programmable BIST control means coupled to the PD, wherein the controller means includes a digital counting means to accumulate the digital signal; and
communication means, wherein the communication means provides the accumulated digital signal from the counting means for an automatic test equipment (ATE) to determine whether the PLL is operating correctly based on the accumulated digital signal.

23. The apparatus of claim 22, wherein the counting means communicates to the ATE via the communication means without affecting the operating characteristics of the phase locked loop (PLL).

24. The apparatus of claim 22, wherein the ATE programs the BIST control means to inject a one or more signal pulses into a charge pumping (CP) means.

25. The apparatus of claim 24, the PLL further comprising a low pass loop filter (LF) means cooperatively coupled to the CP means, wherein the LF means accumulates charge from the CP means to provide a voltage output on the basis of the one or more signal pulses injected into the CP means.

26. The apparatus of claim 25, further comprising a voltage controlled oscillator (VCO) coupled to the LF means, the VCO outputting a frequency on the basis of the voltage output from the LF means.

27. The apparatus of claim 26, further comprising a frequency divide by N (DBN) means coupled to the VCO to output a feedback frequency signal.

28. The apparatus of claim 27, wherein the PD means is coupled to the frequency DBN means, and wherein the PD means receives the N divided feedback frequency signal and a reference frequency signal for the comparison.

29. The apparatus of claim 24, further comprising:
a multiplexer having an output to the CP means and inputs from the PD means and the BIST control means; and
a test enable switch coupled to the multiplexer to receive a control signal from the ATE, wherein the control signal determines whether the multiplexer connects the CP means to the PD means during a mission mode or to the BIST control means during a test mode.

30. The apparatus of claim 22, wherein the PD means includes a frequency detection means.

31. A non-transitory computer readable media including program instructions which when executed by a processor cause the processor to perform the method of self testing a phase locked loop (PLL) built in self test (BIST), comprising:
injecting a series of signal pulses into the PLL to adjust a signal of the PLL;
accumulating in a digital counter a digital signal descriptive of a comparison between the PLL signal and a reference signal; and
determining whether the PLL is operating correctly based on the accumulated digital signal in the digital counter.

32. The non-transitory computer readable media of claim 31, wherein the accumulating does not affect the operating characteristics of the phase locked loop (PLL).

33. The non-transitory computer readable media of claim 31, wherein the determining whether the phase locked loop (PLL) is operating correctly comprises comparing the accumulated counter digital signal to simulated data.

34. The non-transitory computer readable media of claim 33, the method further comprising selecting a pass or fail condition on the basis of the comparison to the simulation.

35. The non-transitory computer readable media of claim 31, wherein the comparing is performed in automated test equipment (ATE) coupled to the PLL BIST.

36. The non-transitory computer readable media of claim 33, wherein the simulated data is a simulated signature of an output of a phase detector during phase locked loop (PLL) start up.

37. The non-transitory computer readable media of claim 31, wherein the injecting comprises transmitting the signal pulses to a charge pump (CP) of the PLL.

38. The non-transitory computer readable media of claim 37, wherein the transmitting comprises providing the signal pulses from a digital controller included in the BIST, wherein the BIST controller is programmable from the ATE.

39. The non-transitory computer readable media of claim 37, further comprising outputting from the CP a charge to a low pass loop filter (LP), wherein the LF generates a voltage on the basis of the charge from the CP.

40. The non-transitory computer readable media of claim 39, further comprising adjusting a voltage controlled oscillator (VCO) output frequency signal on the basis of the voltage supplied from the LP.

41. The non-transitory computer readable media of claim 40, further comprising producing in a phase detector (PD) the digital signal descriptive of the comparison between the reference signal and a signal representative of the VCO output frequency signal.

42. The non-transitory computer readable media of claim 41, further comprising dividing the VCO output frequency signal by an integer N to provide the signal representative of the VCO output frequency signal.
